(19) United States
(12) Patent Application Publication
(10) Pub. No.: US 2016/0204790 A1
(43) Pub. Date: Jul. 14, 2016

(54) DIGITAL-TO-ANALOG CONVERTER, AND MOTOR DRIVING CONTROL APPARATUS AND METHOD USING THE SAME

(71) Applicant: Samsung Electro-Mechanics Co., Ltd., Suwon-si (KR)

(72) Inventors: Jin Yong KANG, Suwon-si (KR); Tah Joon PARK, Suwon-si (KR)

(73) Assignee: Samsung Electro-Mechanics Co., Ltd., Suwon-si (KR)

(21) Appl. No.: 14/972,689

(22) Filed: Dec. 17, 2015

(30) Foreign Application Priority Data
Jan. 12, 2015 (KR) 10-2015-0004317

(51) Int. Cl. H03M 1/08; H03M 1/68; H02P 25/02

(52) U.S. Cl. CPC H03M 1/08; H02P 25/028; H03M 1/68

(57) ABSTRACT

A digital-to-analog converter may include: a signal modulator configured to receive a signal having a first digital value, and modulate the signal having the first digital value to a signal having a second digital value having fewer bits than bits of the signal having the first digital value, or a signal having a value that is periodically changed between the second digital value and a value greater than the second digital value; and a signal converter configured to convert the signal having the second digital value into a signal having an analog value.

### CROSS-REFERENCE TO RELATED APPLICATION(S)

This application claims the benefit of Korean Patent Application No. 10-201 5-000431 7 filed on Jan. 12, 2015, in the Korean Intellectual Property Office, the entire disclosure of which is incorporated herein by reference for all purposes.

### BACKGROUND

1. Field

The present following description relates to a digital-to-analog converter, a motor driving control apparatus, and a method of controlling the driving of a motor using the same.

2. Description of Related Art

In general, a digital-to-analog converter is an apparatus for converting a digital signal to an analog signal.

For example, such a digital-to-analog converter may be used to control a driving apparatus such as a motor. In order to precisely control a driving apparatus, the number of bits of an input signal with a digital value needs to be increased.

However, as the number of input bits of the digital-to-analog converter is increased, circuits capable of significantly reducing influences of noise and distortion may be required. In addition, as the number of bits is increased, since an area of the circuit is increased and distortion compensation, or the like, is required, it may be difficult to design the digital-to-analog converter.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to one general aspect, a digital-to-analog converter includes: a signal modulator configured to receive a signal having a first digital value, and modulate the signal having the first digital value to a signal having a second digital value having fewer bits than bits of the signal having the first digital value, or a signal having a value that is periodically changed between the second digital value and a value greater than the second digital value; and a signal converter configured to convert the signal having the second digital value into a signal having an analog value.

The signal modulator may be configured to modulate the signal having the first digital value to a pulse signal in which one bit in the signal having the second digital value is periodically changed. A duty ratio of the pulse signal may be determined based on the first digital value.

The digital-to-analog converter may further include a bit changer configured to change a number of difference bits between a number of bits of the signal having the first digital value and a number of bits of the signal having the second digital value, wherein the duty ratio of the pulse signal is segmented by the nth power of 2, n being the number of difference bits.

A number of difference bits between a number of bits of the signal having the first digital value and a number of bits of the signal with the second digital value may be 1. The duty ratio of the pulse signal may be 0 or 0.5 and may be determined based on a value of a least significant bit of the signal having the first digital value. Other bits except for the least significant bit of the signal having the first digital value may be used in the signal having the second digital value.

The digital-to-analog converter may further include a counter configured to count and output a value at a predetermined time interval for a period of the signal modulated by the signal modulator, wherein the signal modulator is configured to perform the modulation such that a value of an output signal from the signal modulator is changed when a value output from the counter reaches a preset value.

The signal modulator may be configured to modulate the signal having the first digital value to a pulse signal in which a least significant bit in the signal having the second digital value is periodically changed, wherein the least significant bit is 0 when the value output from the counter is greater than a predetermined value, and the least significant bit is 1 when the value output from the counter is equal to or less than the predetermined value.

The signal modulator may be configured to modulate the signal having the first digital value to a pulse signal in which a least significant bit in the signal having the second digital value is periodically changed, wherein the least significant bit is 1 when the value output from the counter is greater than a predetermined value, and the least significant bit is 0 when the value output from the counter is equal to or less than the predetermined value.

The digital-to-analog converter may further include a corrector configured to correct the analog value such that the signal having the analog value converted by the digital-to-analog converter corresponds to the signal having the first digital value.

According to another general aspect, a motor driving control apparatus includes: a control signal generator configured to generate a control signal having a first digital value for controlling a driving of a motor; a signal modulator configured to modulate the signal having the first digital value to a signal having a second digital value having fewer bits than bits of the signal having the first digital value, or a signal having a value that is periodically changed between the second digital value and a value greater than the second digital value; and a signal converter configured to convert the signal having the second digital value into a signal having an analog value.

The motor driving control apparatus may further include a bit changer configured to change a number of difference bits between a number of bits of the signal having the first digital value and a number of bits of the signal having the second digital value. The signal modulator may be configured to modulate the signal having the first digital value to a pulse signal in which one bit in the signal having the second digital value is periodically changed. A duty ratio of the pulse signal may be segmented by the nth power of 2, n being the number of difference bits.

A number of difference bits between a number of bits of the signal having the first digital value and a number of bits of the signal having the second digital value may be 2. The signal modulator may be configured to modulate the signal having the first digital value to a pulse signal in which one bit in the signal with the second digital value is periodically changed. A duty ratio of the pulse signal may include 0, 0.25, 0.5, or 0.75.

The motor driving control apparatus may further include a counter configured to count and output a value at a predetermined time interval for a period of the signal modulated by the signal modulator, wherein the signal modulator is configured to modulate the signal having the first digital value to a pulse signal in which a least significant bit in the signal having the second digital value is periodically changed, and wherein a value of the least significant bit when a value output from the counter is greater than a predetermined value and a value of the least significant bit when the value output from the counter is equal to or less than the predetermined value are different from each other.

The control signal generator may be configured to generate a control signal for a proportional integral differential (PID) control of the motor, and correct the control signal such that the signal having the analog value converted by the signal converter corresponds to the signal having the first digital value. The motor may include a voice coil motor (VCM).

According to another general aspect, a method of controlling driving of a motor may include: generating, at a control signal generator, a control signal having a first digital value for controlling driving of the motor; modulating, at a signal modulator, the signal having the first digital value to a signal having a second digital value having fewer bits than bits of the signal having the first digital value, or a signal having a value that is periodically changed between the second digital value and a value greater than the second digital value; and converting, at a signal converter, the signal having the second digital value into a signal having an analog value.

The method may further include: counting and outputting a value, by a counter, at a predetermined time interval for a period of the signal modulated by the signal modulator; and changing a value of an output signal from the signal modulator in response to the value output from the counter reaching a preset value.

Other features and aspects will be apparent from the following detailed description, the drawings, and the claims.

### BRIEF DESCRIPTION OF THE DRAWINGS

FIG. 1 is a block diagram illustrating an example of a digital-to-analog converter.

FIG. 2 is a block diagram illustrating an example of a motor driving control apparatus.

FIGS. 3 through 6 are graphs illustrating a signal modulation of a signal modulator included in the digital-to-analog converter, according to an example.

FIG. 7 is a flow chart illustrating an example of a method of controlling driving of a motor.

FIG. 8 is a flow chart illustrating a more specific example of a method of controlling driving of a motor.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

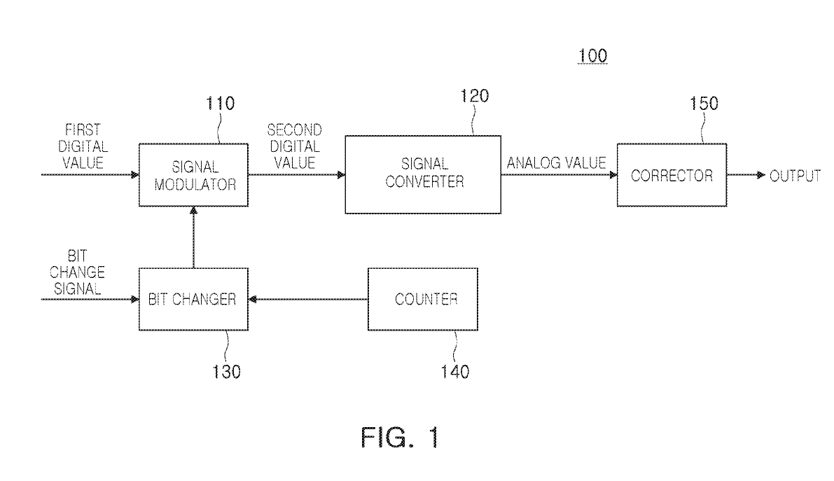

FIG. 1 is a block diagram illustrating a digital-to-analog converter 100 according to an example.

Referring to FIG. 1, a digital-to-analog converter 100, according to an example, may include a signal modulator 110, a signal converter 120, a bit changer 130, a counter 140, and a corrector 150.

The signal modulator 110 modulates a signal having a first digital value input thereto to a signal having a digital value having fewer bits than that of the first digital value, or modulates the signal having the first digital value to a signal having a value that is periodically changed between a second digital value and a value greater than the second digital value. For example, when the number of bits of the signal having the first digital value is 12 bits, the number of bits of the signal having the second digital value may be 11 bits or fewer.

Here, the signal having the second digital value may be a signal having a constant value, or may be a signal of which a value is periodically changed between a value less than the second digital value and a value greater than the second digital value. For example, when a least significant bit of the first digital value is 0, the signal having the second digital value may be the signal having the constant value.

For example, when the least significant bit of the signal having the first digital value is 1, the signal having the value that is periodically changed may be a pulse signal having a value for one period that is a low value (a second digital value) or a high value (a second digital value +1). Here, a mean value of the signal may be greater than the low value and less than the high value. Thereby, the signal may have more various values than the second digital value. That is, the signal modulated by the signal modulator 110 may have more information than the signal with the second digital value.

Meanwhile, the values of the signal are not limited to two, and a difference value between the values of the signal is also not limited to 1. For example, the signal may be a sine wave signal of which a mean value corresponds to the first digital value.

The signal converter 120 may convert the signal having the second digital value into a signal having an analog value. Here, the analog value may be a value corresponding to the first digital value.

For example, when the least significant bit of the first digital value is 0, the signal converter 120 may intactly convert a signal output from the signal modulator 110 into a signal having the analog value.

For example, when the least significant bit of the signal having the first digital value is 1,the signal converter 120 converts the signal output from the signal modulator 110 into a signal having the analog value at a predetermined time interval. That is, since the signal output from the signal modulator 110 is a signal having the second digital value and the value greater than the second digital value, the signal converter 120 periodically converts the signal output from the signal modulator 110 into a signal having the analog value. Thus, the signal converter 120 finally outputs a signal having an analog value corresponding to a median value between the second digital value and the value greater than the second digital value.

Thus, the signal converter 120 may perform high-resolution digital-to-analog high-resolution conversion, even if the signal converter 120 has a relatively low resolution.

The bit changer 130 changes the number of difference bits between the number of bits of the signal having the first digital value and the number of bits of the signal having the second digital value. For example, when the number of bits of the signal having the first digital value is 12 bits, the number of bits of the signal having the second digital value may be 11 bits or fewer. Here, the bit changer 130 may change the number of bits of the signal having the second digital value to 11 bits or bits fewer than 11 bits.

Thus, a duty ratio of the signal modulated by the signal modulator 110 may be segmented by the nth power of 2, wherein n denotes the number of difference bits.

For example, when n is 2, the duty ratio of the signal modulated by the signal modulator 110 may be 0, 0.25, 0.5, or 0.75. That is, as a value of n is increased, the signal modulator 110 more precisely modulates the signal, and thus the digital-to-analog converter 100 may perform relatively higher resolution digital-to-analog conversion.

In addition, the bit changer 130 changes the number of difference bits, and thus the digital-to-analog converter 100 may perform the digital-to-analog conversion at various resolutions even in a case in which resolution of the signal converter 120 is fixed.

The counter 140 counts and outputs a predetermined time interval for a period of the signal modulated by the signal modulator 110. Here, the signal modulator 110 may perform the modulation so that a value of an output signal is changed when a value output from the counter 140 reaches a preset value. Thus, even in a case in which the least significant bit of the signal having the first digital value is 1, the signal converter 120 accurately performs a conversion operation.

The corrector 150 corrects the analog value so that the signal having the analog value converted by the signal converter 120 corresponds to the signal having the first digital value.

For example, when the signal having the first digital value is 3 bits and the signal having the second digital value is 2 bits, a maximum code which may be converted by the digital-to-analog converter 100 may be 6. For example, when the signal having the first digital value is 110 or 111, the output value of the digital-to-analog converter 100 may be the same.

That is, in a case in which the signal converter 120 having an input of n-bits and resolution of m-bits is used, the maximum code may be 2ⁿ−2^{(n-m)}. Therefore, the corrector 150 corrects the value output from the signal converter 120 based on the first digital value, whereby conversion accuracy of the digital-to-analog converter 100 is improved.

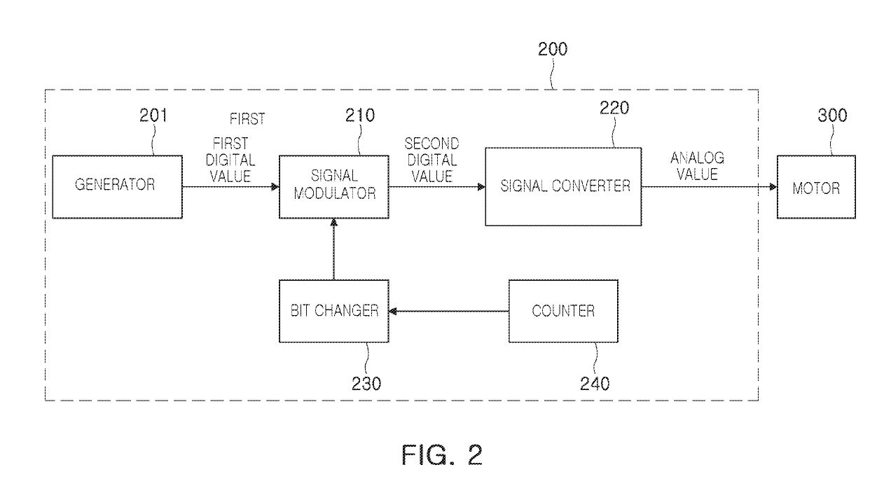

FIG. 2 is a block diagram illustrating a motor driving control apparatus 200 according to an example.

Referring to FIG. 2, the motor driving control apparatus 200 includes a control signal generator 201, a signal modulator 210, a signal converter 220, a bit changer 230, and a counter 240. Further, the motor driving control apparatus 200 controls driving of a motor 300.

Since the signal modulator 210, the signal converter 220, the bit changer 230, and the counter 240 perform the same functions as those of the signal modulator 110, the signal converter 120, the bit changer 130, and the counter 140 included in the digital-to-analog converter 100 described above with reference to FIG. 1, an overlapping description of contents that are the same as or correspond to the above-mentioned contents will be omitted.

The control signal generator 201 generates a control signal for controlling the driving of the motor as a first digital value. For example, the control signal generator 201 may generate a control signal for a proportional integral differential (PID) control of the motor.

In addition, the control signal generator 201 corrects the control signal so that the analog value converted by the signal converter 220 corresponds to the first digital value. That is, the control signal generator 201 may serve as the corrector 150.

The motor 300 may include a voice coil motor (VCM). For example, the VCM may be used in an optical image stabilizer (OIS) for reducing an occurrence of shaking at the time an image is photographed. The OIS may use the VCM to compensate for the shaking by moving a lens or a sensor in a direction in which the shaking is concealed.

Examples of a method for controlling the motor 300 may include a switching method and a linear method. The switching method is a method in which ON and OFF operations are repeated per a predetermined period using a pulse width modulation (PWM) signal. Since the switching method performs position control using the ON and OFF operations, it may be simply implemented. The linear method is a method in which a predetermined amount of voltage or current is applied to the motor using a digital-to-analog converter. The linear method may precisely control the motor 300.

The motor driving control apparatus 200, according to an example, effectively uses the switching method and the linear method. Thus, the motor driving control apparatus 200 rapidly controls the motor 300 by simply performing digital-to-analog conversion at relatively low resolution and precisely controls the motor by performing the digital-to-analog conversion at relatively high resolution.

In addition, the motor driving control apparatus 200 reduces an area of a circuit and reduces a load of distortion compensation by performing the digital-to-analog conversion operation at high resolution using the low resolution signal converter 220.

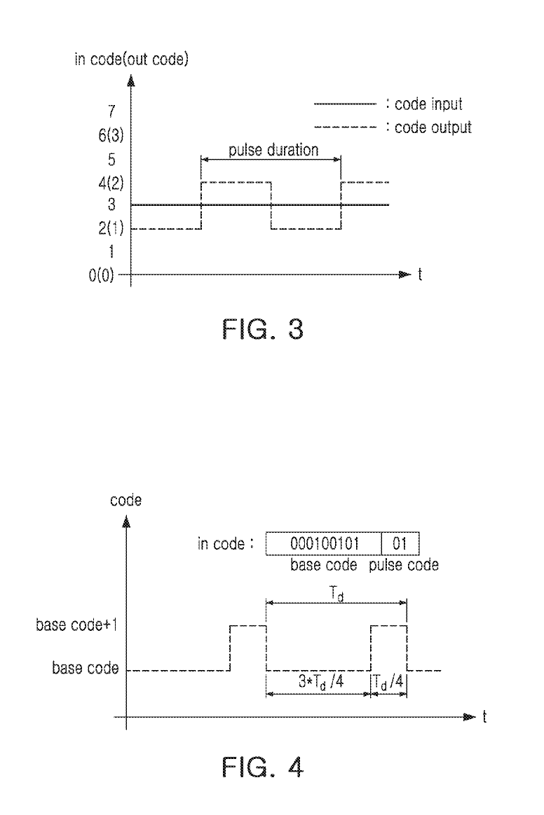

FIGS. 3 through 6 are graphs illustrating signal modulation of the signal modulator 110 included in the digital-to-analog converter 100, according to an example.

Referring to FIG. 3, a horizontal axis denotes a time, and a vertical axis denotes a digital value. A value indicated in parentheses on the vertical axis denotes the second digital value. Here, the number of bits of the signal with the first digital value is 3, and the number of bits of the signal with the second digital value is 2.

For example, when the first digital value is 011, the signal modulated by the signal modulator 110 may be a pulse signal of which a value for one period is 010 (second digital value of 01) or 100 (second digital value of 10). Here, since the duty ratio of the pulse signal is 0.5, a median value of the pulse signal is 011. Thus, the analog value converted by the signal converter 120 may be a value corresponding to the digital value of 011.

For example, in a case in which the number of difference bits between the number of bits of the signal having the first digital value and the number of bits of the signal having the second digital value is 1, the duty ratio of the pulse signal may be 0 or 0.5, and may be determined depending on a value of the least significant bit of the signal with the first digital value. Here, other bits except for the least significant bit of the first signal having the digital value may be intactly used in the signal having the second digital value.

Referring to FIGS. 4 through 6, a horizontal axis denotes a time, and a vertical axis denotes a digital value. The number of difference bits between the number of bits of the signal having the first digital value and the number of bits of the signal having the second digital value may be 2.

Referring to FIG. 4, in a case in which the first digital value is 000010010101, the signal modulated by the signal modulator 110 may be a pulse signal of which a value for one period (T_{d}) is 000010010000 or 000010010100. Here, since the duty ratio of the pulse signal is 0.25, the median value of the pulse signal is 000010010001.

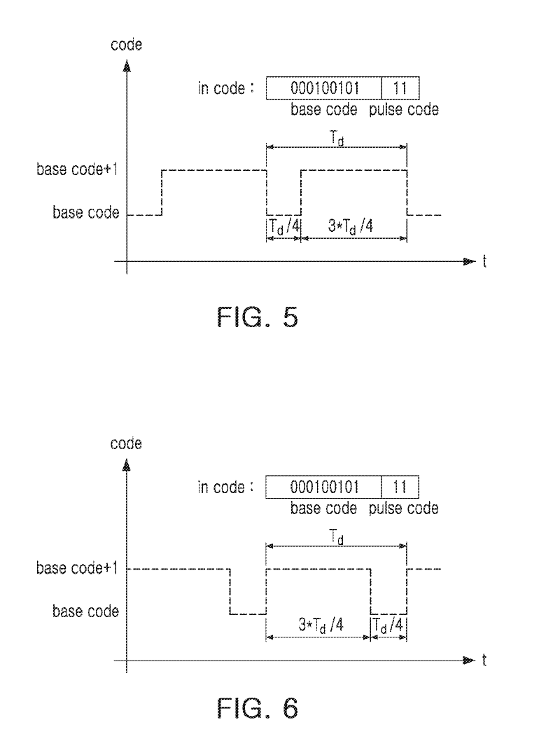

Referring to FIG. 5, in a case in which the first digital value is 000010010111,the signal modulated by the signal modulator 110 may be a pulse signal of which a value for one period is 000010010000 or 000010010100. Here, since the duty ratio of the pulse signal is 0.75, the median value of the pulse signal is 000010010011.

Here, the duty ratio of the pulse signal modulated by the signal modulator 110 may be 0, 0.25, 0.5, or 0.75.

Referring to FIG. 6, the signal modulated by the signal modulator 110 may have a value greater than the second digital value for one period and may then have the second digital value.

Here, the signal modulated by the signal modulator 110 may be controlled depending on a count value of the counter 140. For example, in a case in which two bits of the signal having the first digital value is 11, a value of the signal modulated by the signal modulator 110 may fall at a moment in which the count value becomes 11.

For example, in a case in which a value output from the counter 140 is greater than a predetermined value, the least significant bit of the signal having the second digital value may be 0, and in a case in which the value output from the counter 140 is equal to or less than the predetermined value, the least significant bit of the signal having the second digital value may be 1.

For example, in a case in which the value output from the counter 140 is greater than the predetermined value, the least significant bit of the signal having the first digital value may be 1, and in a case in which the value output from the counter 140 is equal to or less than the predetermined value, the least significant bit of the signal having the second digital value may be 0.

That is, a value of the least significant bit of the signal having the first digital value in the case in which the value output from the counter 140 is greater than the predetermined value and a value of the least significant bit of the signal having the first digital value in the case in which the value output from the counter 140 is equal to or less than the predetermined value may be different from each other.

The signal modulated by the signal modulator 110 is controlled depending on the count value of the counter 140, whereby the signal modulator 110 simply modulates the signal.

Hereinafter, a method of controlling driving of a motor, according to an example, will be described. Since the method of controlling the driving of a motor is performed by the digital-to-analog converter 100 or the motor driving control apparatus 200 described above with reference to FIG. 1, an overlapping description for contents that are the same as or correspond to the above-mentioned contents will be omitted.

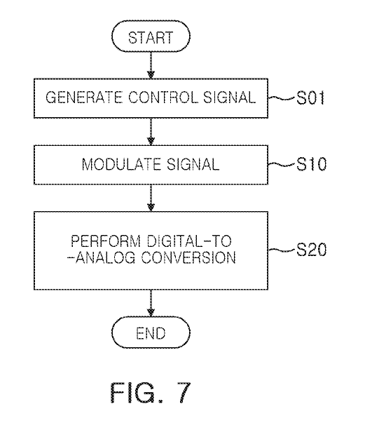

FIG. 7 is a flow chart illustrating a method of controlling driving of a motor according to an example.

Referring to FIG. 7, the method of controlling the driving of a motor includes a control signal generation operation S01, a signal modulation operation S10, and a digital-to-analog conversion operation S20.

In the control signal generation operation S01, the motor driving control apparatus 200 generates a control signal for controlling the driving of a motor 300 as a first digital value.

In the signal modulation operation S10, the motor driving control apparatus 200 modulates the signal having the first digital value to a signal having a second digital value that has fewer bits than that of the signal with the first digital value, and is periodically changed.

In the digital-to-analog conversion operation S20, the motor driving control apparatus 200 converts the signal having the second digital value into a signal having an analog value.

As a result, in the method of controlling the driving of a motor, according to an example, high-resolution digital-to-analog conversion may be performed using the low-resolution signal converter 220.

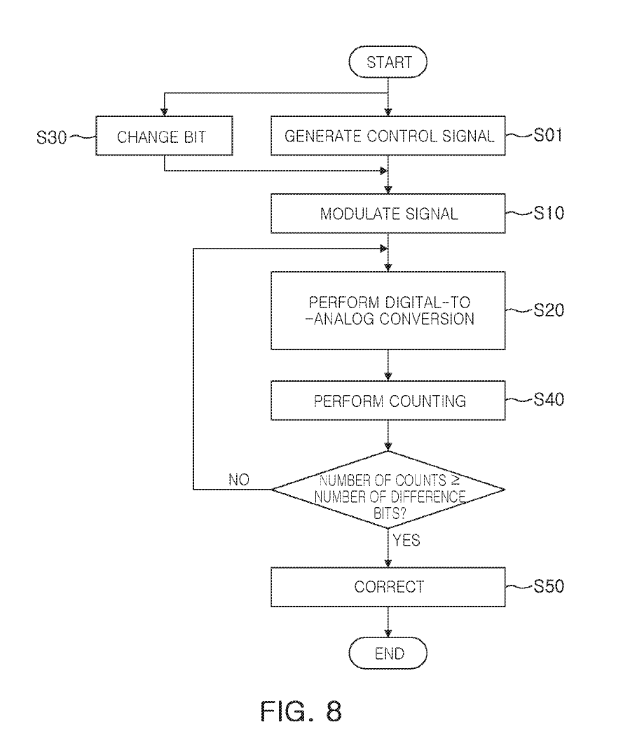

FIG. 8 is a flow chart more specifically illustrating the method of controlling the driving of a motor 300, according to an example.

Referring to FIG. 8, the method of controlling the driving of the motor 300 further includes a bit-changing operation S30, a count operation S40, and a correction operation S50.

In the bit-changing operation S30, the motor driving control apparatus 200 changes the number of difference bits between the number of bits of the signal having the first digital value and the number of bits of the signal having the second digital value. Thus, even in a case in which resolution of the digital-to-analog conversion operation S20 is fixed, the digital-to-analog conversion may be performed at various resolutions.

In the count operation S40, the motor driving control apparatus 200 counts and outputs a number at a predetermined time interval for a period of the signal modulated in the signal modulation operation S10. Here, as the number of difference bits increases, the number counted in the count operation S40 increases. As a result, the signal is simply modulated in the signal modulation operation S10.

In the correction operation S50, the motor driving control apparatus 200 corrects the analog value so that the analog value converted in the digital-to-analog conversion operation S20 corresponds to the first digital value. As a result, even in a case in which the digital-to-analog conversion is performed at relatively high resolution, accuracy of the digital-to-analog conversion is improved.

As set forth above, according to examples disclosed herein, high-resolution digital-to-analog conversion may be performed using a low-resolution digital-to-analog converter (e.g., signal converter 120/220).

The apparatuses, units, modules, devices, and other components (e.g., the signal modulator, signal converter, corrector, bit changer, counter and control signal generator) illustrated in FIGS. 1 and 2 that perform the operations described herein with respect to FIGS. 7 and 8 are implemented by hardware components. Examples of hardware components include controllers, sensors, generators, drivers, and any other electronic components known to one of ordinary skill in the art. In one example, the hardware components are implemented by one or more processors or computers. A processor or computer is implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices known to one of ordinary skill in the art that is capable of responding to and executing instructions in a defined manner to achieve a desired result. In one example, a processor or computer includes, or is connected to, one or more memories storing instructions or software that are executed by the processor or computer. Hardware components implemented by a processor or computer execute instructions or software, such as an operating system (OS) and one or more software applications that run on the OS, to perform the operations described herein with respect to FIGS. 7 and 8. The hardware components also access, manipulate, process, create, and store data in response to execution of the instructions or software. For simplicity, the singular term “processor” or “computer” may be used in the description of the examples described herein, but in other examples multiple processors or computers are used, or a processor or computer includes multiple processing elements, or multiple types of processing elements, or both. In one example, a hardware component includes multiple processors, and in another example, a hardware component includes a processor and a controller. A hardware component has any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 7 and 8 that perform the operations described herein with respect to FIGS. 1 and 2 are performed by a processor or a computer as described above executing instructions or software to perform the operations described herein.

Instructions or software to control a processor or computer to implement the hardware components and perform the methods as described above are written as computer programs, code segments, instructions or any combination thereof, for individually or collectively instructing or configuring the processor or computer to operate as a machine or special-purpose computer to perform the operations performed by the hardware components and the methods as described above. In one example, the instructions or software include machine code that is directly executed by the processor or computer, such as machine code produced by a compiler. In another example, the instructions or software include higher-level code that is executed by the processor or computer using an interpreter. Programmers of ordinary skill in the art can readily write the instructions or software based on the block diagrams and the flow charts illustrated in the drawings and the corresponding descriptions in the specification, which disclose algorithms for performing the operations performed by the hardware components and the methods as described above.

The instructions or software to control a processor or computer to implement the hardware components and perform the methods as described above, and any associated data, data files, and data structures, are recorded, stored, or fixed in or on one or more non-transitory computer-readable storage media. Examples of a non-transitory computer-readable storage medium include read-only memory (ROM), random-access memory (RAM), flash memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, magnetic tapes, floppy disks, magneto-optical data storage devices, optical data storage devices, hard disks, solid-state disks, and any device known to one of ordinary skill in the art that is capable of storing the instructions or software and any associated data, data files, and data structures in a non-transitory manner and providing the instructions or software and any associated data, data files, and data structures to a processor or computer so that the processor or computer can execute the instructions. In one example, the instructions or software and any associated data, data files, and data structures are distributed over network-coupled computer systems so that the instructions and software and any associated data, data files, and data structures are stored, accessed, and executed in a distributed fashion by the processor or computer.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A digital-to-analog converter comprising:
a signal modulator configured to receive a signal having a first digital value, and modulate the signal having the first digital value to
a signal having a second digital value having fewer bits than bits of the signal having the first digital value, or
a signal having a value that is periodically changed between the second digital value and a value greater than the second digital value; and
a signal converter configured to convert the signal having the second digital value into a signal having an analog value.

2. The digital-to-analog converter of claim 1, wherein the signal modulator is configured to modulate the signal having the first digital value to a pulse signal in which one bit in the signal having the second digital value is periodically changed, and
a duty ratio of the pulse signal is determined based on the first digital value.

3. The digital-to-analog converter of claim 2, further comprising a bit changer configured to change a number of difference bits between a number of bits of the signal having the first digital value and a number of bits of the signal having the second digital value,
wherein the duty ratio of the pulse signal is segmented by the nth power of 2, n being the number of difference bits.

4. The digital-to-analog converter of claim 2, wherein:
a number of difference bits between a number of bits of the signal having the first digital value and a number of bits of the signal with the second digital value is 1;
the duty ratio of the pulse signal is 0 or 0.5 and is determined based on a value of a least significant bit of the signal having the first digital value; and
other bits except for the least significant bit of the signal having the first digital value are used in the signal having the second digital value.

5. The digital-to-analog converter of claim 1, further comprising a counter configured to count and output a value at a predetermined time interval for a period of the signal modulated by the signal modulator,
wherein the signal modulator is configured to perform the modulation such that a value of an output signal from the signal modulator is changed when a value output from the counter reaches a preset value.

6. The digital-to-analog converter of claim 5, wherein:
the signal modulator is configured to modulate the signal having the first digital value to a pulse signal in which a least significant bit in the signal having the second digital value is periodically changed; and
the least significant bit is 0 when the value output from the counter is greater than a predetermined value, and the least significant bit is 1 when the value output from the counter is equal to or less than the predetermined value.

7. The digital-to-analog converter of claim 5, wherein:
the signal modulator is configured to modulate the signal having the first digital value to a pulse signal in which the least significant bit in the signal having the second digital value is periodically changed; and
the least significant bit is 1 when the value output from the counter is greater than a predetermined value, and the least significant bit is 0 when the value output from the counter is equal to or less than the predetermined value.

8. The digital-to-analog converter of claim 1, further comprising a corrector configured to correct the analog value such that the signal having the analog value corresponds to the signal having the first digital value.

9. A motor driving control apparatus comprising:
a control signal generator configured to generate a control signal having a first digital value for controlling a driving of a motor;
a signal modulator configured to modulate the signal having the first digital value to
a signal having a second digital value having fewer bits than bits of the signal having the first digital value, or
a signal having a value that is periodically changed between the second digital value and a value greater than the second digital value; and
a signal converter configured to convert the signal having the second digital value into a signal having an analog value.

10. The motor driving control apparatus of claim 9, further comprising a bit changer configured to change a number of difference bits between a number of bits of the signal having the first digital value and a number of bits of the signal having the second digital value,
wherein the signal modulator is configured to modulate the signal having the first digital value to a pulse signal in which one bit in the signal having the second digital value is periodically changed, and
wherein a duty ratio of the pulse signal is segmented by the nth power of 2, n being the number of difference bits.

11. The motor driving control apparatus of claim 9, wherein:
a number of difference bits between a number of bits of the signal having the first digital value and a number of bits of the signal having the second digital value is 2;
the signal modulator is configured to modulate the signal having the first digital value to a pulse signal in which one bit in the signal with the second digital value is periodically changed; and
a duty ratio of the pulse signal includes 0, 0.25, 0.5, or 0.75.

12. The motor driving control apparatus of claim 9, further comprising a counter configured to count and output a value at a predetermined time interval for a period of the signal modulated by the signal modulator,
wherein the signal modulator is configured to modulate the signal having the first digital value to a pulse signal in which a least significant bit in the signal having the second digital value is periodically changed, and
wherein a value of the least significant bit when a value output from the counter is greater than a predetermined value and a value of the least significant bit when the value output from the counter is equal to or less than the predetermined value are different from each other.

13. The motor driving control apparatus of claim 9, wherein the control signal generator is configured to generate a control signal for proportional integral differential (PID) control of the motor, and correct the control signal such that the signal having the analog value converted by the signal converter corresponds to the signal having the first digital value, and
the motor includes a voice coil motor (VCM).

14. A method of controlling driving of a motor, comprising:
generating, at a control signal generator, a control signal having a first digital value for controlling driving of the motor;
modulating, at a signal modulator, the signal having the first digital value to
a signal having a second digital value having fewer bits than bits of the signal having the first digital value, or
a signal having a value that is periodically changed between the second digital value and a value greater than the second digital value; and
converting, at a signal converter, the signal having the second digital value into a signal having an analog value.

15. The method of claim 14, further comprising:
counting and outputting a value, by a counter, at a predetermined time interval for a period of the signal modulated by the signal modulator; and
changing a value of an output signal from the signal modulator in response to the value output from the counter reaching a preset value.
